(19) United States
(12) Patent Application Publication
(10) Pub. No.: US 2008/0195912 A1
(43) Pub. Date: Aug. 14, 2008

(54) METHOD OF COMMUNICATOIN

(75) Inventors: Stefan Mende, Recklinghausen (DE); Dominik Lenz, Luedinghausen (DE); Markus Mueller, Marl (DE); Radha Krishna Atukula, Bochum (DE); Dirk Uffman, Haltern am See (DE); Wolfgang Wilhelm, Herne (DE)

Correspondence Address: FOLEY & LARDNER LLP, P.O. BOX 80278, SAN DIEGO, CA, 92138-0278, US

(73) Assignee: Nokia Corporation

(21) Appl. No.: 11/675,018

(22) Filed: Feb. 14, 2007

(51) Int. Cl. H03M 13/03

(52) U.S. Cl. 714/752

(57) ABSTRACT

A sending node comprising a processor configured to generate an error checking message, said error checking message being generated from data, said error checking message providing order information; and a transmitter configured to transmit said error checking message and said data.

### FIELD OF THE INVENTION

The present invention relates to a method of communication between a transmitting node and a receiving node. The present invention also relates to a transmitting node and to a receiving node. In particular, but not exclusively, embodiments of the present invention provide an error detection mechanism.

### BACKGROUND TO THE INVENTION

Known communication environments can be quite varied. For example, within a single device or entity, there may be communications between different functionalities or nodes within that device. Alternatively, two or more devices may be connected together and there may be communications between two or more of the devices. It is known to have two devices communicating with each other via one or more devices such as in the context of a packet data network, a mobile communications network or the like.

In the context of this document, the term node can refer to a functionality in a single device and communication may for example be between two nodes within a single device. The term node, as used in the context of this document also encompasses the device itself and two nodes in the form of two different devices may communicate directly or indirectly. The term node is also intended to cover a functionality in one device which is able to communicate with a node in the form of a different device or a functionality in a different device.

In data packet networks, thermal noise or electromagnetic interference can produce bit errors in the transfer data. If these bit errors are not detected and properly corrected, the following problems can occur:

Firstly, the data payload of a packet can be corrupted. Typically this is the case when the payload part of a packet is corrupted while the header and footer, if present, of the packet are intact. Alternatively, only the header may be available and not the footer.

A second problem is that one or more packets can be lost completely. This may occur if the header of a packet is corrupted. Eventually, the beginning of the following packets can no longer be detected by the receiver, thus resulting in the loss of one or more packets. Another reason may be that the input buffer of the receiver has been filled up so that the receiver is currently unable to store any more packets.

A third problem is that packets can be duplicated or inserted. This occurs in networks with re-transmission capabilities. For example, this error can occur when the sender re-transmits one or more packets because the sender has not received an acknowledgement for these packets in time, for example due to a blockage in the link from the receiver to the sender. If the receiver is not able to detect that the packet has been sent before, the receiver will accept those packets again so they would be duplicated.

These problems are independent of network topology and can occur in any single link or point to point connection of a network.

Some methods have been proposed to solve the above-mentioned problems. In particular, there were a number of different communication protocols which have been defined in order to solve the above-mentioned problems. Typically, these communications protocol use a combination of two separate mechanisms to achieve this.

One mechanism is to protect the packet with a check sum of a cyclic redundancy check CRC such as a CRC-16 or CRC-32. CRC-16 has polynomial order of 16 and a polynomial length of 17 bits whilst CRC32 has polynomial order of 32 and a polynomial length of 33 bits. When the received check sum does not match the check sum calculated from the received data, the receiver discards the packet. This is able to address the first problem discussed previously but does not address the second and third problems.

The second mechanism which is known is to attach a sequence number to each packet, for example in the header or the footer. This sequence number is incremented for each packet including possible wrap-around. The second problem mentioned can be solved with this method because the receiver can request re-transmission of packets from the sender and the receiver detects a gap in the received sequence numbers. For example, packets numbers 5, 6, 8 and 9 are received, packet number 7 is determined to have been lost and that it should be re-transmitted. The third problem can also be solved with this mechanism. For example, if packets number 5, 6, 7, 5, 6, 7, 8 are received, it is simple matter for the receiver to determine that the second occurrence of packets numbered 5, 6 and 7 are re-transmissions and can be ignored by the receiver.

Protocols using the above schemes are for example, X.25, IEEE802.2 and RapidIO. These known methods all combine a check sum method with a sequence number method.

However, the known arrangements require two separate mechanisms for dealing with errors which increases the overhead associated with error correction.

A communication protocol may have the capability of detecting and correcting errors introduced on the communication channel. Correction may be based on the reliability that is normally defined and implemented by the Data Link Layer of a given communication protocol.

The basis for reliable transmission in a communication protocol is that a source node transmits a data packet to a destination node. The source node has to store the transmitted packet until it receives an acknowledgement ACK that the packet has been correctly received by the receiving node. If that is the case, the packet can be removed from the buffer of the sending node. If an acknowledgement is not received in time from the receiving node, the packet is re-transmitted. The sender is not allowed to send any other data packets as long as the sending node has not received an acknowledgement from the receiving node. This method is known as stop and wait Automatic Repeat-reQuest (ARQ).

This mechanism may be extended with a negative acknowledgement (NAK) which is transmitted if the receiving node detects an error based on an error detection mechanism, for example the CRC check sum that is used for each transmitted packet. However, this method is not particularly efficient due to the fact that each packet is acknowledged individually which increases the latency and the utilisation is limited a very small fraction of the available bandwidth.

One known method which addresses this concern is the Go Back N ARQ. In the Go Back N ARQ, each packet is assigned a sequence number by the transmitting node. This number is used for identifying a packet in the sending node and the receiving node. On the sending node side, the sequence number is used for storing data packets in the buffer until the ACK is received for those packets and for deleting data packets in the buffer after an acknowledgement is received. The sequence numbers help in accessing and organising re-transmission if an acknowledgement is not received in time. The use of sequence numbers allows for the transmission of several consecutive packets without receiving acknowledgement for each and every packet. This is called window acknowledgement and the window's size is limited by the number of unique sequence numbers which is normally half of the highest value a sequence number can take.

The receiving node has to keep track of the sequence numbers to identify the next expected packet, to detect a potential re-transmission or to detect a loss of packets. The receiving node is able to acknowledge each packet separately or in a group that results in acknowledging of all previously received packets including the packets identified by the sequence number which is transmitted with that acknowledgement.

If a sending node does not receive an acknowledgement in a given time, it will go back to the sequence number included in the last received acknowledgement from the receiving node and will start with the re-transmission of the packet associated with the following sequence number.

This scheme is sometimes used in conjunction with a negative acknowledgement NAK which is triggered by the receiving node as soon as an error, for example a CRC check sum error, is detected. The NAK can include either the sequence number of the next expected packet or the sequence number of the last good received one. The sending node initiates a re-transmission starting from the sequence number that has been reported or from the sequence number that follows the one reported by the NAK. This generally assists in faster error recovery.

Furthermore there are some use cases where there is a need to communicate data to the receiver within the same traffic class or virtual channel in reliable and unreliable packets. The selection possibility of the reliable or unreliable transmission is required on a per-packet basis. This issue is not recognised or addressed by the known systems.

Embodiments of the present invention aim to address one or more of the above-discussed problems.

### SUMMARY OF THE INVENTION

### STATEMENT OF INVENTION

According to one aspect of the present invention, there is provided a sending node comprising a processor configured to generate an error checking message, said error checking message being generated from data, said error checking message providing order information; and a transmitter configured to transmit said error checking message and said data.

According to another aspect of the present invention, there is provided a sending node comprising processor means for generating an error checking message, said error checking message being generated from data, said error checking message providing order information; and transmitter means for transmitting said error checking message and said data.

According to a further aspect of the present invention, there is provided a method comprising generating an error checking message from data, said error checking message providing order information; and transmitting said error checking message and said data.

According to a further aspect of the present invention, there is provided a computer readable medium having computer executable components comprising a computer executable component configured to generating an error checking message from data, said error checking message providing order information.

According to another aspect of the present invention, there is provided a receiving node comprising a processor configured to generate an error checking message, said error checking message being generated from received data, said error checking message providing order information and to determine if said received data has been correctly received in dependence on said error checking message.

According to another aspect of the present invention, there is provided a receiving node comprising means for generating an error checking message, said error checking message being generated from received data, said error checking message providing order information; and means for determining if said received data has been correctly received in dependence on said error checking message.

According to another aspect of the present invention, there is provided a method comprising generating an error checking message from received data, said error checking message providing order information; and determining if said received data has been correctly received in dependence on said error checking message.

According to another aspect of the present invention, there is provided a computer readable medium having computer executable components comprising a first computer executable component configured to generate an error checking message from received data, said error checking message providing order information; and a second computer executable component configured to determine if said received data has been correctly received in dependence on said error checking message.

### BRIEF DESCRIPTION OF DRAWINGS

For a better understanding of the present invention and as to how the same may be carried into effect, reference will now be made by way of example only to the accompanying drawings in which:

FIG. 1 shows a sender node and a receiver node according to a first embodiment of the present invention;

FIG. 2 shows a flow chart for the sending node;

FIG. 3 shows a flow chart for the receiving node;

FIG. 4 shows a message sequence when the data is correctly received;

FIG. 5 shows a message sequence in which a packet is lost;

FIG. 6 shows a message sequence in which a packet is corrupted by a bit error;

FIG. 7 shows a message sequence in which a packet is re-transmitted;

FIG. 8 shows a sending node and a receiving node accordingly to a further embodiment of the present invention;

FIG. 9 shows a message sequence with an ACK message after a single packet;

FIG. 10 shows a message sequence with an ACK message after a block of packets have been received;

FIG. 11 shows a message sequence with a NACK mechanism for an incorrectly received packet; and

FIG. 12 shows a message sequence where an ACK message is not received.

### DETAILED DESCRIPTION OF PREFERRED EMBODIMENTS

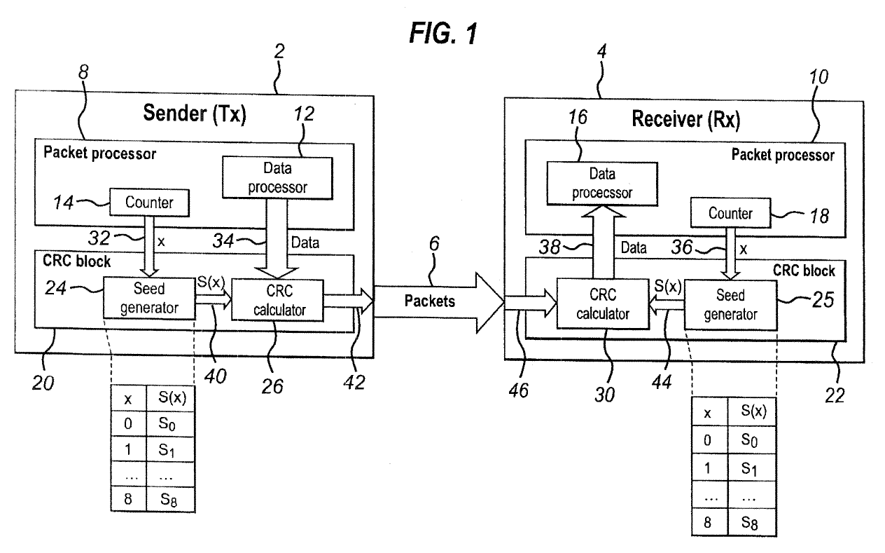

A first embodiment of the present invention will now be described with reference to FIGS. 1 to 7.

FIG. 1 shows a sender node 2 which is arranged to transmit packets via a connection 6 to a receiver node 4. It should be appreciated that in embodiments of the present invention, the sender and receiver nodes may be provided in a single device or may be provided in separate devices. The connection 6 between the sender node 2 and the receiver node 4 may be a wired connection or a wireless connection. Embodiments of the present invention are applicable where the sender node 2 is directly connected to the receiver node 4. In other words, there is a single link between the sender node 2 to the receiver node 4. However, it should be appreciated that embodiments of the present invention are also applicable to transmissions between a sender node 2 and a receiver node 4 which go via one or more other nodes.

The sender node 2 comprises a packet processor 8 which is arranged to perform packet processing. The packet processor 8 comprises a counter 14 and a data processor 12 arranged to perform data processing.

The sender node 2 also comprises a CRC block 20. The CRC block 20 has a seed generator 24 and a CRC calculator 26. The counter 14 is connected via connection 32 to the seed generator 24. The seed generator 24 is connected via connection 40 to the CRC calculator 26. The data processor 12 is connected to the CRC calculator via connection 34. The CRC calculator 26 has an output 42 which provides a packet to be transmitted via connection 6.

A receiver node 4 has a packet processor 10. Again this is arranged to perform packet processing. The packet processor 10 has a data processor 16 and a counter 18.

A CRC block 22 is provided. This has a CRC calculator 30 and a seed generator 28. The counter 18 is connected to the seed generator 28 via connection 36. The CRC calculator 30 is arranged to output data via connector 38 to the data processor 16. The seed generator provides an output to the CRC calculator 30 via a connection 44. The CRC calculator 30 receives packets via input 46 from the connection 6.

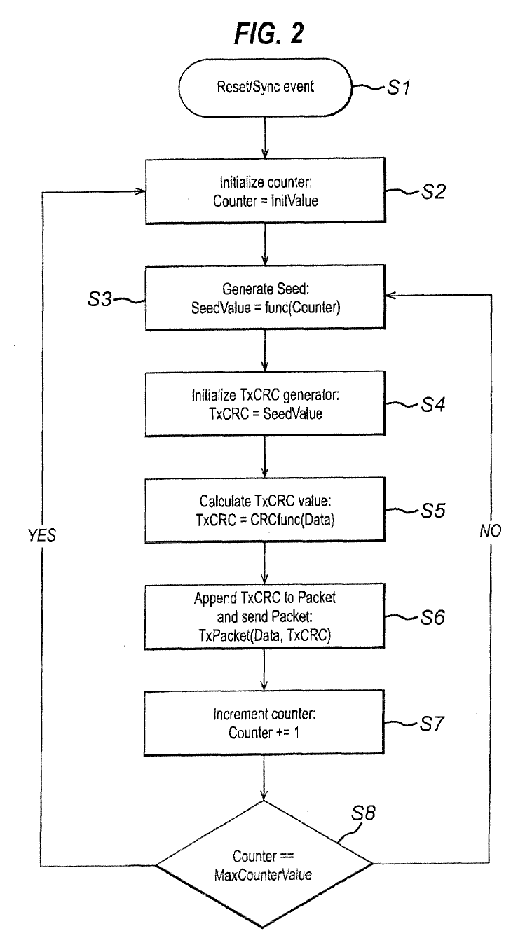

The function of the elements of the receiver and sender nodes will now be explained with reference to the FIGS. 2 to 7.

In embodiments of the present invention, it is not necessary to provide a separate sequence number, identity or tag in or attached to a data packet which is transmitted by the sender. In embodiments of the present invention, each packet is secured by a CRC check sum. However, in embodiments of the present invention, the CRC seed value is modified i.e. is different from packet to packet. This contrasts with the known methods which use the same CRC seed values for all packets.

Cyclic redundancy check CRC is a type of hash function which is used to produce a check sum, that is small fixed number of bits, against a block of data. In embodiments of the present invention, that block of data comprises a packet of data. The function of a check sum is used to detect errors after transmission or storage. The CRC is computed and appended before transmission and verified afterwards by the recipient to confirm that no changes occur on transit.

A CRC check sum is the remainder of binary division with no bit carry of the message bit stream by a predefined bit stream of length N which represents the co-efficient of the CRC polynomial.

Embodiments of the present invention use the property of a CRC that for a given data, a change in the seed initial value causes a change in node CRC check sum. The seed value can be envisaged as the initial value stored in a memory or generated by a logic unit, which is shifted or is fed to the CRC calculator before calculation of CRC of a message. The maximum width of the seed value is equal to the order of the CRC polynomial. This is a result of the property that a CRC can detect burst error lengths up to the order of the generator polynomial. The difference of two seed values will always correspond to a bust error with a length less than the CRC polynomial order. Therefore, any change in seed value can be detected, provided the data is intact.

The number of different CRC seed values used is called the “seed window”. In general, the seed window can be of any size but is restricted by the order of the polynomial.

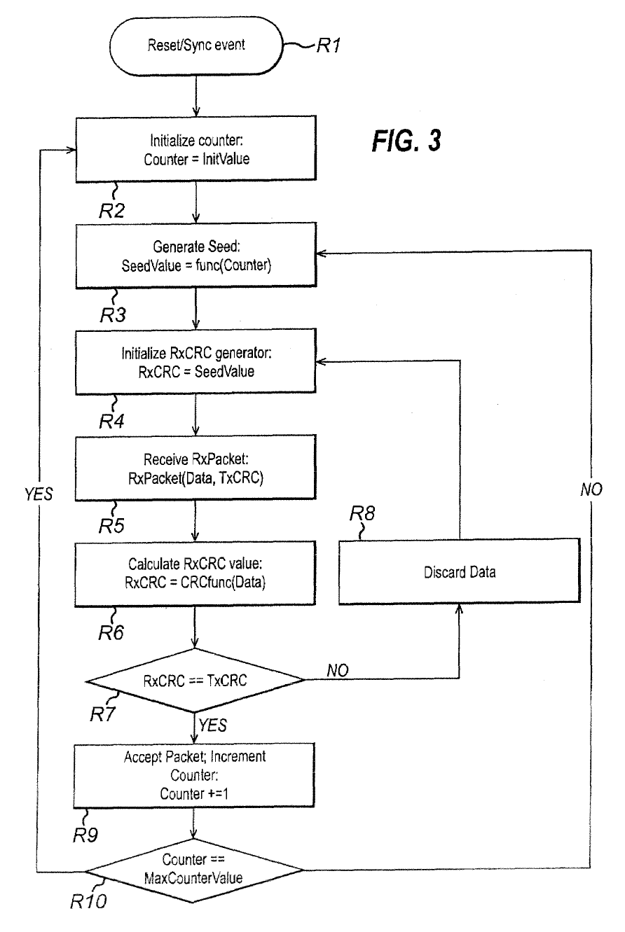

FIG. 2 shows a flow chart of the operations carried out by the sender node. FIG. 3 shows the flow chart of the operations carried out at the receiver node.

Reference is first made to FIG. 2. In the sender node 2, a reset or synchronisation event is detected in step S1.

In step S2, the counter 14 is initialised. In other words, the value of the counter is set to the initialisation value.

In step S3, the value of the counter 14 is used by the seed generator 24 to generate a seed. The seed value is a function of the counter value. The counter value is received by the seed generator 24 from the counter 14 via connection 32. In one implementation, the seed generator 24 comprises a look-up table, as illustrated in FIG. 1. The value X of the counter is used to look-up a corresponding seed value S(X). In an alternative implementation, the seed generator may perform a calculation or perform an algorithm or use a logic unit to generate the seed value.

In step S4, the seed value S(X) is received by the CRC calculator 26. The CRC calculator is initialised with the received seed value.

In step S5, the CRC value is calculated by the CRC calculator 26. The CRC value calculated is a function of the data and uses the seed value as the initial value. The data used by the CRC calculator is received from the data processor 12 of the packet processor 8.

In step S6, the calculated CRC is appended to the packet. This may be done in the CRC calculator or elsewhere, in alternative embodiments of the present invention. The packet is then output by output 42 and transmitted to the receiver.

In step S7, the counter is incremented by 1. A check is then made to see if the counter has reached its maximum value in step S8.

If the counter has reached to a predefined value, then the next step will be step S2 in which the counter is initialised again. If, on the other end, the counter has not reached the predefined value, then the next step is step S3 and the new seed value is determined.

Reference is now made to FIG. 3 which shows the method steps which are carried out in the receiver node 4. In step R1, a reset or synchronisation event is determined. This may be the same event that causes the sender node 2 to be reset or synchronised. Alternatively, the events may be generated simultaneously or more or less at the same time in both the sender and the receiver.

In step R2, the counter 18 is initialised to its initial value in response to the reset or synchronisation event.

In step R3, the output of the counter X is received by the seed generator 28 via connection 36. The value of the counter, X, is used to provide the seed value. This is carried out in a similar manner to that explained in relation to the sender node.

In step R4, the CRC calculator 30 receives the seed value S(x) from the seed generator 28 via connection 44. This is used to initialise the CRC generator.

In step R5, the CRC calculator 30 which has received the packet transmitted from the sender extracts the data from the received packet and sends the data to the data processor 16 via connection 38. The CRC value of the received packet is also extracted.

In step R6, the CRC calculator uses the received data and the seed value from the seed generator to calculate a CRC value.

In step R7, the CRC calculator 30 compares the CRC value which is generated based on the received data and the seed value provided by the seed generator with the actually received CRC value in the received packet. If two CRC values are not the same, then the next step is R8.

In step R8, the data packet is discarded by the data processor 16. The next step after step R8 will be step R4.

If the two CRC values are the same, the next step is step R9. The data of the data packet is accepted by the data processor 16. The counter is also incremented by 1.

In step R10, a check is made to see whether or not the incremented value of the counter is equal to the predefined value. If so, the next step is step R2 where the counter is initialised.

If, on the other hand, the value is less than the predefined value, then the next step is R3.

Thus, the CRC seed values are generated locally at the sender node and the receiver node but are not transmitted with the packet data. Thus, after system setup, e.g. reset, the access position and possibly the update scheme to the seed window of the sender node and the receiver node need to be synchronised. In some embodiments of the present invention additional synchronisation packets may be provided for this purpose.

Any access method, for example sequential, for the seed window can be utilised at sender and receiver as long as it gives the same seed values with the subsequent accesses to the seed window at the sender node and the receiver node. The seed window may be repeated in a cyclic manner if more seed values are needed than the seed window size.

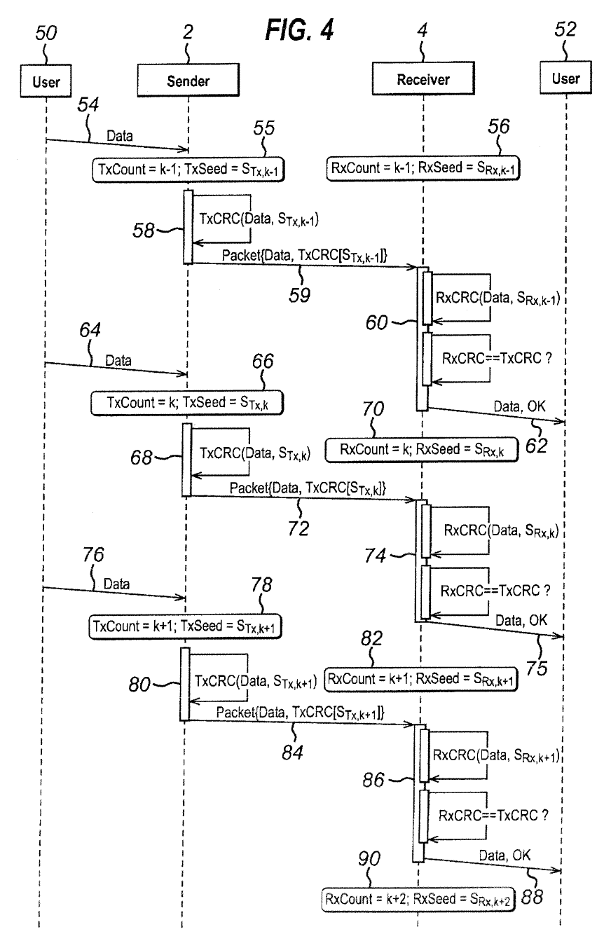

Reference will now be made to FIGS. 4, 5, 6 and 7. Each of these diagrams shows a message sequence chart.

FIG. 4 shows a case where there are no transmission errors. All check sums calculated by the receiver match the check sums sent by the sender because the data is uncorrupted and the counters are synchronous. Thus, the receiver seed values always match the sender seed values.

The user 50 is associated with the sending node 2 and user 52 is associated with receiver node 4. The user 50 sends data in step 54 to the sender node 2. In the sender in step 55, the counter is set to value k−1 and the transmission seed is set to S_{Tx,k-1}. In the receiver in step 56, the counter is set to the value k−1 and the receiving seed value is set to S_{Rx,k-1}. Steps 55 and 56 may take place at more or less the same time.

In step 58 the CRC value is calculated in the sender node. In step 59, a packet including the data and the calculated CRC values are transmitted to the receiver.

In step 60, a CRC value is calculated based on the seed value generated in the receiver using the received data. This is then compared to the received CRC value.

In step 62, data is deemed to be correctly received and is passed to the user 52.

The next set of data is passed from the user 50 to the sender node 2 in step 64. The value of the counter is incremented to k and the new seed value is S_{Tx,k} in step 66.

The CRC value is calculated in the sender 2 in step 68. A packet is then transmitted including the data and the calculated CRC value, in step 72.

As indicated by step 70, the receiver increments the counter value to k and provides the new seed value S_{Rx,k}. This occurs before the next packet of data has been received by the receiver. These values in step 74 determine whether or not the received value of the CRC and the locally calculated value of the CRC are the same.

In this case, the values are the same and the data is sent to the user in step 75 along with an indication that the data has been correctly received.

As indicated by steps 76 to 90, the procedure is repeated with counter being incremented to k+1 in both the sender and receiver nodes with a corresponding update of the seed values.

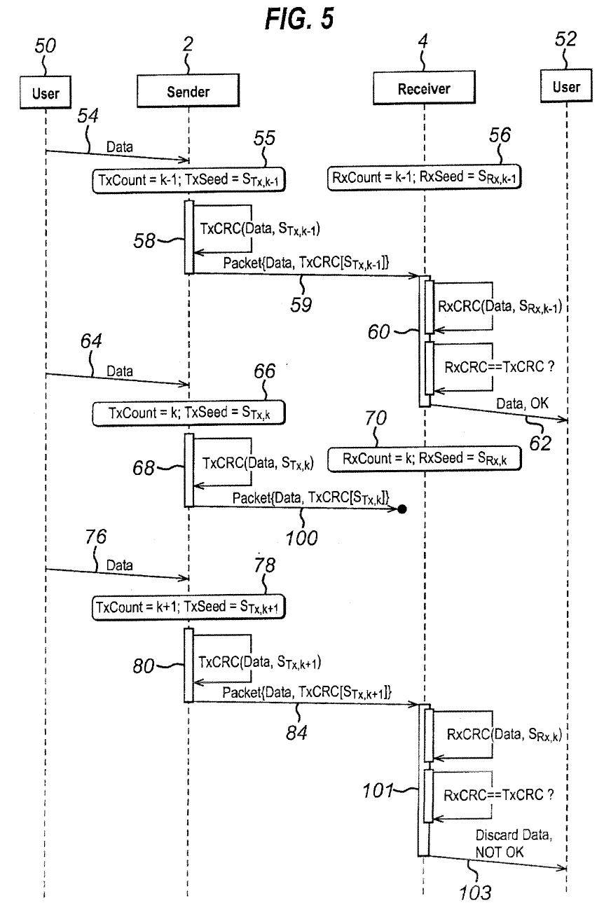

FIG. 5 shows the message sequence where the kth packet is lost due to a transmission error. Thus, the part of the message flow corresponding to steps 54 to 68 of FIG. 4 also occur in the example shown in FIG. 5.

However, the second packet, the k packet is not received in step 100 by the receiver 4.

Steps 76, 80 and 84 are then carried out as shown in FIG. 4 with the k+1 packet. The sender is using the counter and seed value associated with the k+1 packet.

However, the counter in the receiver is only at value k and not k+1 as in the sender because the kth packet has not been received by the receiver. Accordingly, there will be a difference between the calculated CRC value and the received CRC value since different seed values are used, in step 101. Accordingly, the receiver node 4 will discard the data in step 103.

In one embodiment of the invention, a negative acknowledgement NAK may be sent back to the sender to force a retransmission.

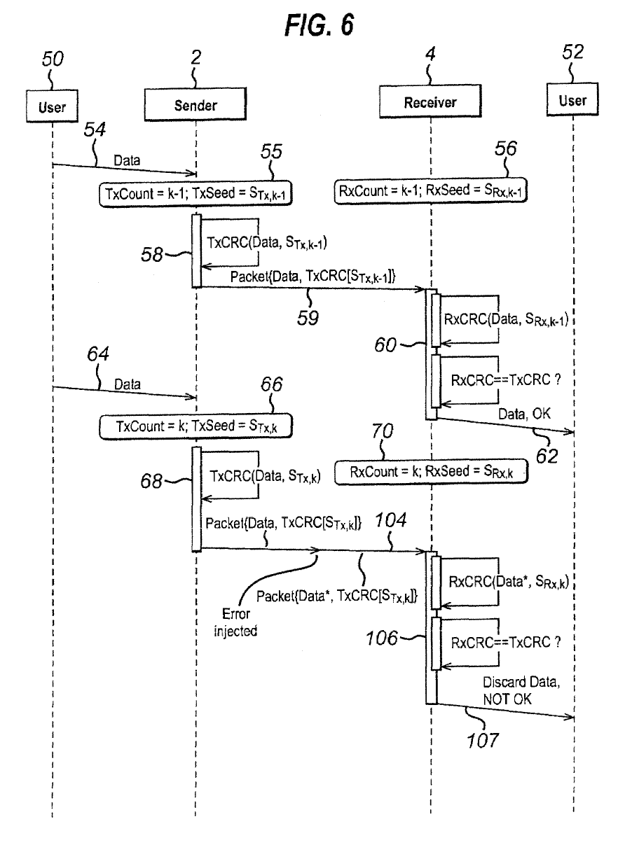

Reference is now made to FIG. 6. In this example, packet k is corrupted by a bit error. Accordingly, those steps referenced from numeral 54 to 70 in FIG. 6 are the same as described in relation to FIG. 4.

However, in step 104 the kth packet is transmitted but there is an error and the packet is corrupted. Accordingly, in step 106, in the receiver, because the data is corrupted, this will result in the CRC calculated based on the received data being different from the received CRC. Thus, the data is discarded in step 107.

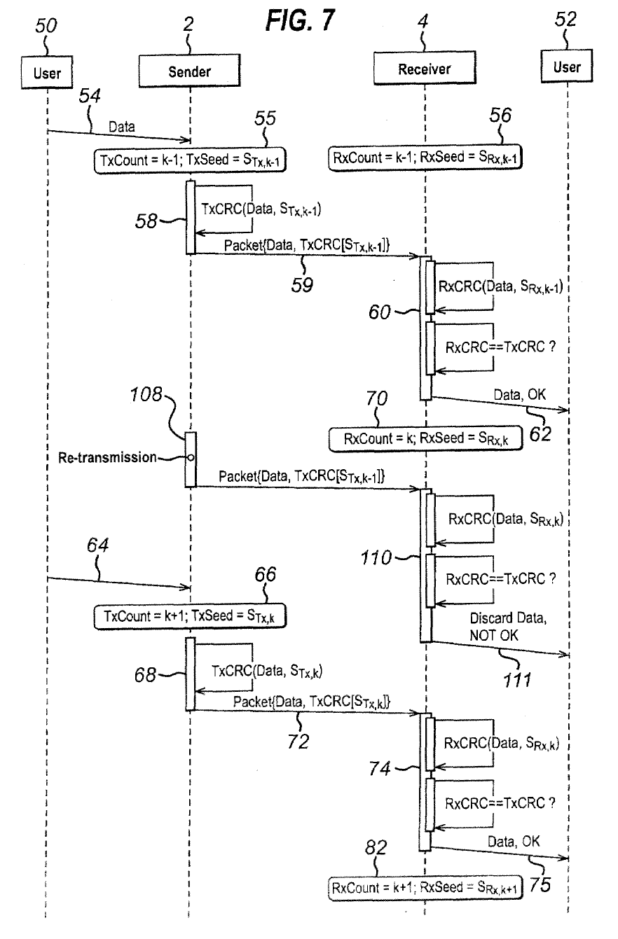

Reference is now made to FIG. 7. In this example, the packet k−1 is re-transmitted for one reason or another.

Those steps referenced by numbers 54 to 62 and step 70 are as described in relation to FIG. 4. In step 108, the data is re-transmitted by the sender. In step 110, there is a check at the receiver between the locally generated CRC and the received CRC. The locally generated CRC is based on the seed value associated with the kth packet whereas the received CRC is based on the seed value associated with the k−1 packet. Thus, the two CRC values are different. Accordingly, the data is discarded in step 111.

Steps 64 to 82 are as described in relation to FIG. 4 and are the correctly received kth packet. Because the previous packet was discarded, the counter has not been incremented at the receiver. Accordingly, the counter correctly provides the value associated with the kth packet which in turn means that the correct seed value is used. The data is thus correctly received.

Thus, the arrangement of FIG. 7 shows that embodiments of the present invention are such that the receiver is able to ignore the re-transmitted packet.

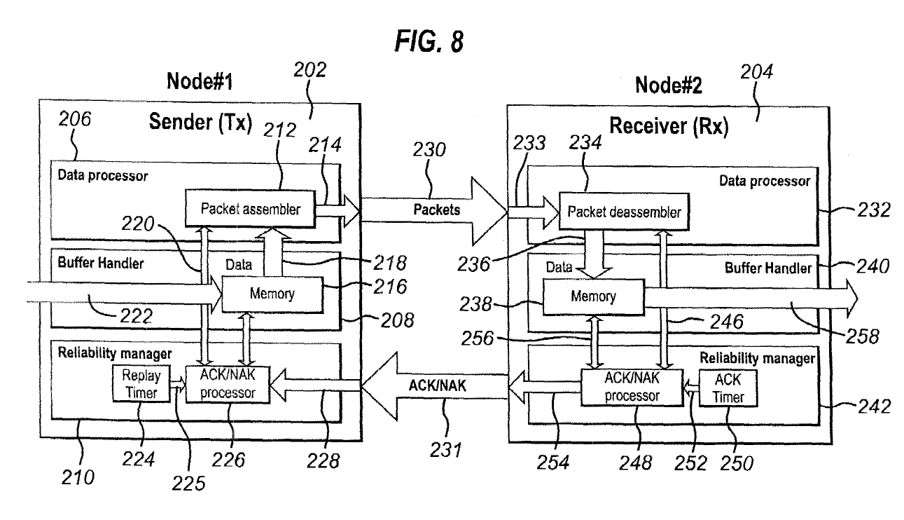

Reference is now made to FIG. 8 which shows a further embodiment of the present invention. In the further embodiment of the present invention, the method of using CRC initial values to ensure correctness and in order delivery of data packets, as described in relation to the first embodiment is used. A counter and seed generator is provided at both the sending node 202 and receiving node 204 although for simplicity, these elements are not shown.

The sender node 202 comprises a data processor 206, a buffer handler 208 and a reliability manager 210. The data processor 206 comprises a packet assembler 212. The buffer handler comprises a memory 216. The reliability manager comprises a replay timer 224 and an ACK/NAK signal processor 226. The packet assembler 212 is connected to the ACK/NAK processing via connection 220. The packet assembler 212 is arranged to receive data from the memory 216 via connection 218. Packets are output via the packet assembler 212 at output 214. The buffer handler is arranged to receive data to be transmitted via input 222, said data being stored in the memory 216. The memory 216 is connected to the ACK/NAK processor 226 via connection 227. The ACK/NAK processor 226 is arranged to receive the ACK/NAK signals from the receiver 204 via input 228. The replay timer 224 is connected to the ACK/NAK processor 226 via connection 225.

Packets are transmitted from the sending node 202 to the receiving node 204 via connection 230. The ACK/NAK signals are sent from the receiving node 204 to the sending node 202 via connection 231. As mentioned previously, the connections between the nodes may be wired and/or or wireless connections.

The receiver receiving node 204 comprises a data processor 232, a buffer handler 240 and a reliability manager 242. The data processor is arranged to have an input 233 to receive packets transmitted by the sending node and a packet deassembler 234. The buffer handler 240 comprises a memory 238 which is arranged to receive data from the packet deassembler 234 via connection 236. The memory 238 is arranged to output data via output 258.

The reliability manager 242 comprises an ACK timer 250 which is connected via connection 252 to an ACK/NAK processor 248. The ACK/NAK processor 248 is connected to the packet deassembler 234 via connection 246. The ACK/NAK processor 248 is additionally connected to the memory 238 via connection 256 and provides an output via output 254 of the ACK/NAK signal to be transmitted to the sending node 202.

In broad terms, data to be transmitted by the sending node 202 is received by the buffer handler 208 via input 222 and is stored in memory 216. The data is retained in the memory until an acknowledgement is received that the data has been received by the receiver 204. Thus, when the data has been correctly received by the receiver and then the associated ACK signal has been received via the reliability manager 210, this causes the associated data to be removed from the memory. However, if a packet has not been correctly received and an NAK signal is instead received, that causes the data associated with the incorrectly or not received packet to be re-sent.

The NAK message may or may not include information about the last correctly received packets. In one possible implementation, the NAK could be a packet including the seed counter value or seed value. In an alternative implementation, there could be a sequence that consists of an ACK followed directly by a NAK that does not include any seed counter value or seed value information The packet assembler 212 puts together the packet which is to be sent. This packet assembler thus can be considered to include the packet processing and CRC block of the sending node 2 shown in FIG. 1.

In broad terms, the receiving node 204 receives a packet and de-assembles it. The packet deassembler 234 can be regarded as including the packet processor and CRC block of the receiver node 4 shown in FIG. 1. The received data is input to the memory from which the data can be output. The packet de-assembler 234 is connected to the ACK/NAK processor to provide an indication as to whether or not a packet has been correctly received. This ACK/NAK processor 248 can be used to control the memory. For example, if it is determined by a CRC error, the data has not been correctly received, the temporarily stored data associated with that packet may be deleted before it is output.

Thus, in embodiments of the present invention, the receiving node reacts either with an ACK if the packet or packets have been correctly received or with a NAK in case an error was detected by the CRC check. The ACK and NAK can be used for a single or a group acknowledgement. The size of the seed counter portion, or a part of or complete seed counter value, that is transmitted in the ACK/NAK packet may depend on the acknowledgement window (that is the number of packets which can be acknowledged together).

After an error is detected, for example due to a CRC check sum discrepancy, a NAK is transmitted and the NAK generation is disabled in the receiving node until a packet is correctly received. However, the receiving node is not blocked from receiving a packet. Rather, the receiving node waits for a packet that should be correctly received.

As with the previously described embodiments, the sending node 202 increments the receive counter whenever a new seed is to be generated. This seed counter value is used for generating a seed value to initiate the CRC register. As with the previous embodiment, the seed values are different in successive packets.

In an embodiment, the minimum number of different seed values used in successive packets should be greater than the acknowledgment window size.

The seed counter on the receiver side is incremented with every correctly received packet. If an error is detected, the seed counter on the receiver side is not incremented and hence the seed value is not updated. Thus, this means that the same seed value is used for the next received packet. In embodiments of the invention, the receiving node includes part of the receive node seed counter value in the ACK/NAK packet to acknowledge correctly the received packet. For example to allow an acknowledgement window size of 16, at least 5 bits of the seed counter value are needed. This value is used instead of the sequence number of the prior art. Alternatively the ACK/NAK message may include all or part of the seed value.

A different embodiment of the invention may use for example an acknowledgement window size of 15. In that case, at least 4 bits of the seed counter value need to be transmitted in the ACK/NAK messages.

The sender removes the relevant numbered packet from the buffer (memory) corresponding to the part of seed counter value that is received with the ACK/NAK packet from the receiver.

A detailed embodiment of the invention will be described. The figures given are by way of illustration only. In this detailed embodiment, a seed counter in both the transmitting node and a receiving node is six bits giving a value of 0 to 63 for the counter. The acknowledgment window size is selected as 16 meaning the maximum number of allowed outstanding packets is 16. The minimum seed counter part used in the ACK/NAK is five bits, which is greater than the acknowledgement window size. These five bits are the five least significant bits of the seed counter in the receiving node.

The replay timer 224 in the sending node is used to guard against the loss of the ACK or NAK signals. Whenever this timer is expired, a replay timer expired event is generated which triggers re-transmission from the sending node to the receiving node. A replay timer is started or re-started after the sender transmits a data packet and after an ACK or NAK is received. The timer is stopped when all the transmitted data packets are acknowledged.

Similarly, the ACK timer 250 in the receiver is used to trigger an acknowledgement before the transmitter starts a re-transmission due to an expired replay timer. When the ACK timer is expired, an ACK timer expired event is generated which triggers an ACK transmission. The ACK timer is started or re-started whenever the receiver receives a new packet correctly, i.e. without error from the sender and is stopped when all the received packets are acknowledged.

In an embodiment of the present invention, the data structure of the ACK and NAK packets is such that they include part of the receiver seed counter value associated with the last correctly received packet. After being reset, this value included in ACK or NAK is initialised to 31.

In the transmission (sender) node 202, the seed counter value used to identify the seed value of the next packet to be sent. This is as described in relation to the first embodiment. Furthermore, a register is provided to store the information of the seed counter value which depends on the information received in the last ACK or NAK packet. This value is initialised to 63 i.e. the maximum size of the counter.

The receiving node is arranged to handle the seed counter value to identify the seed value that it should use in the next expected packet. The register may store the information of the seed counter value that is partly transmitted in the last ACK or NAK packet. This value is initialised to 63.

A message sequence with a single data packet transmission with the ACK triggering due to the expiry of the ACK timer is now described.

Initially, in both the sender and the receiver there are two counters. In the sender, this identifies the next packet to send and the seed counter value associated with the last packet which is acknowledged. Similarly, in the receiver, the counter indicates which packet is the next packet to be received and the last packet which has been acknowledged by that receiver. Based on the value of these counters, the sending node 2 sends the appropriate packet to the receiver. At the receiver, once it is established that the packet is correctly received, this commences a timer. This is the ACK timer. It should be appreciated that the sending and receiving of the packet causes the next to send counter and the next to receive counter to be incremented in the sender and the receiver, respectively.

The acknowledgement signal sent by the receiving node 4 to the sender will include the seed value or the seed counter value associated with the received packet. This will cause the acknowledged packet counters to be incremented in both the sender and the receiver.

It should be appreciated that any suitable event can cause the acknowledgement timer to start. For example, it may be when it is determined that the CRC of the received packet is the same as the locally generated CRC value or it may be earlier.

In an embodiment of the present invention, the acknowledgement message will include the seed value or seed counter value of the current packet. However, it is conceivable that in some embodiments of the present invention, the seed value of a preceding or succeeding packet may be used.

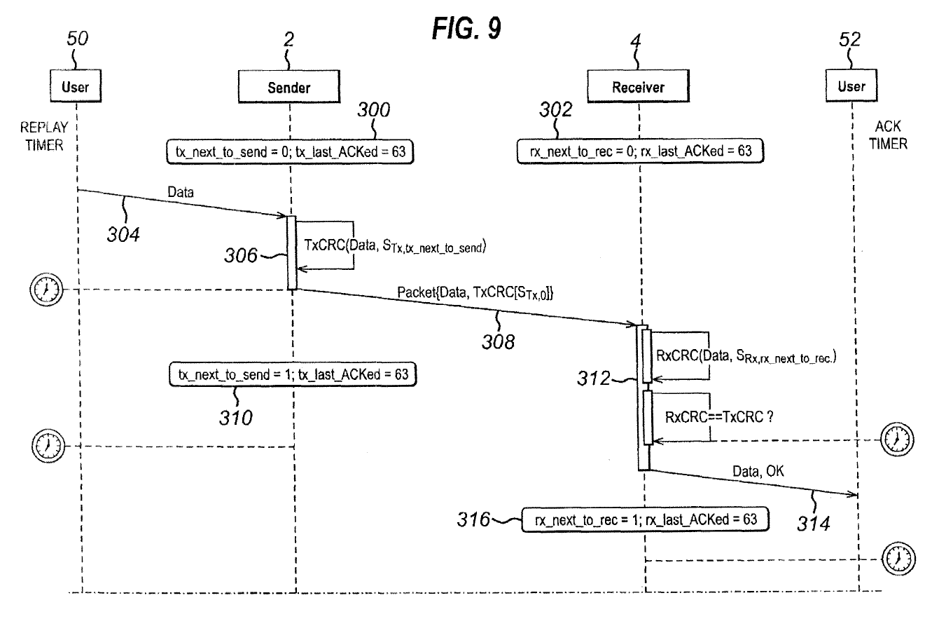

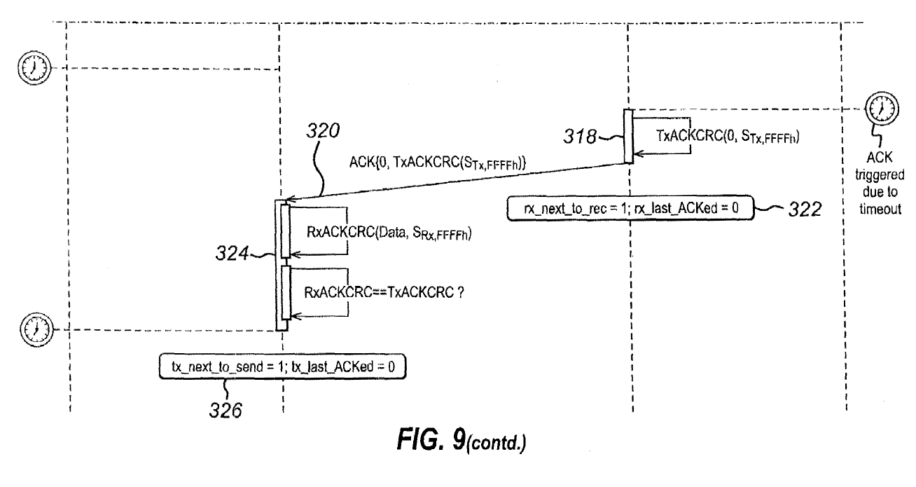

Reference is made to FIG. 9 shows the message flow in which a single packet is acknowledged.

In more detail, FIG. 9 shows:

In step 300, the counter is set to next packet to send is packet 0 and the last packet acknowledged is packet 63 in the sender 2. At a similar time in step 302, the counter is set to next packet to receive is packet 0 and the last packet acknowledged by the receiver is packet 63 in the receiver 4.

In step 304, the user provides data to the sender 2. In step 306, the sender calculates the CRC and transmits the packet in step 308. In step 310, the sender increments the values of the next to send packet to 1.

In set 312, the receiver receives the packet, calculates a local CRC value as described previously and compares that locally calculated CRC value with the received CRC value.

In FIG. 9, the values are the same and the data is passed in step 314 to the user 52 by the receiver 4. In step 316, in the receiver 4 the counter is incremented so the next packet to be received is expected to be packet 1.

In step 318, the ACK timer expires. The ACK time is started by for example the receipt of the data, the determination of the matching of the CRC values or by any other suitable event. An ACK packet is formulated including the CRC value, the seed value used to determine the CRC value, the seed count value or any part of the above values or a combination of two or more of the above.

In step 322, the counter is incremented in the receiver to indicate that the last packet acknowledged is packet 0.

In step 320, this packet is sent to the sender 2. In step 324, the sender will delete the packet which has been acknowledged. In some embodiments of the invention, the information is only used if the CRC checksum calculated local is equivalent to the received one.

In step 326, the counter in the sender is updated to reflect the number of the packet last acknowledged by the receiver, that is packet 0.

In one modification, the acknowledgement signal is only sent after a block of packets has been received. Accordingly, each packet which is sent and received will cause the sending node to increment its counter for the next packet to send and to increment the counter for the next packet to receive in the case of the receiving node. In this example, the first packet is 0 and the last packet is the 15^{th} packet. The acknowledgement signal is triggered due to reception of the acknowledgment window size data packets which have not been acknowledged. In other words, a number of packets have been received which is the maximum number of outstanding packets that are allowed. On determining that 16 packets have been received and which have not been acknowledged, this causes the acknowledgement signal to be sent from the receiver to the sender. The acknowledgement message will include the seed counter value associated with the packet last received (the 15^{th} packet). This will cause the last acknowledged packet in both the sending node and the receiving node to be updated to packet number 15, in this example.

To implement this function, the receiver is arranged to count the number of packets which are correctly received.

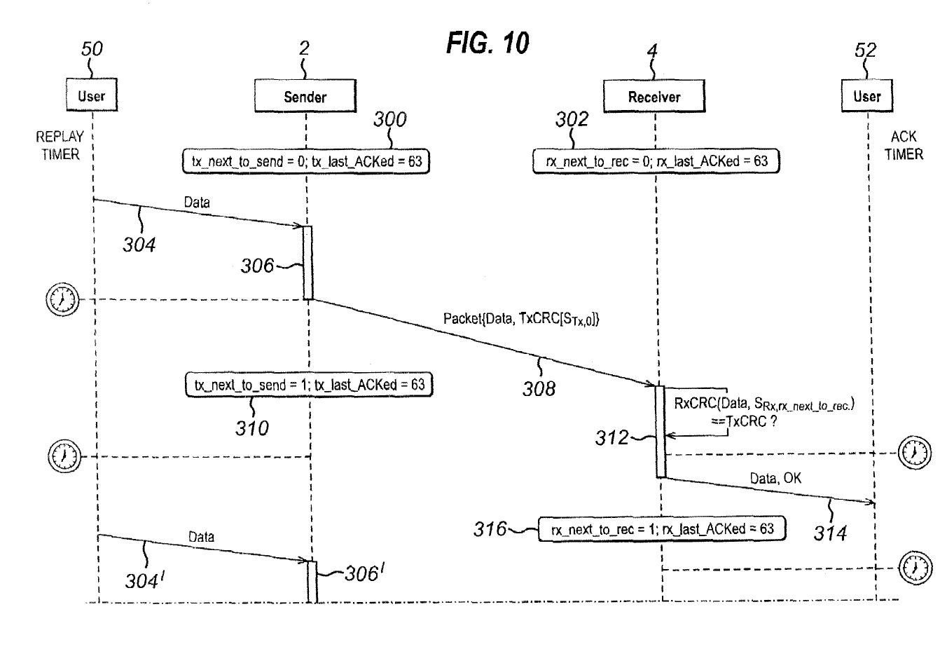

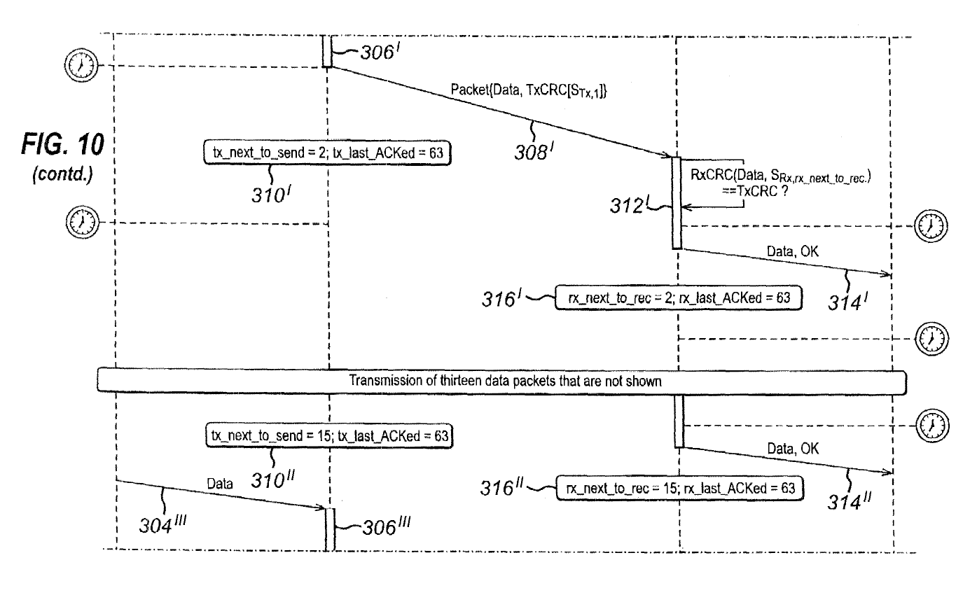

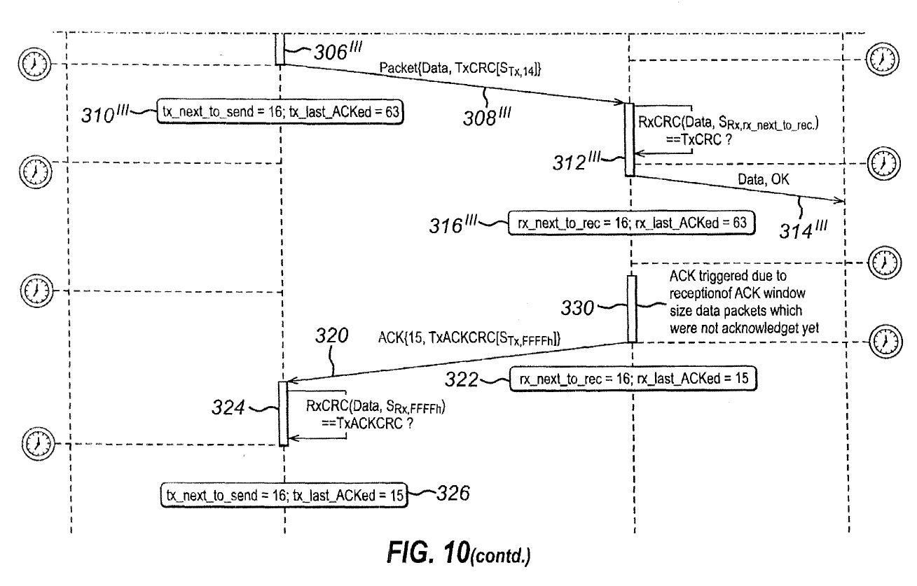

In this regard, reference is made to the message flow of FIG. 10. Steps 304 to 316 are as in FIG. 9. However there is no ACK after a single packet. Rather the next packet is sent. Steps 304′ to 316′ correspond respectively to steps 304 to 316 but in respect of packet 1. This procedure is repeated with the next 13 packets.

Steps 310″ to 316″ correspond to steps 310 to 316 but in respect of the packet number 14.

Steps 304′″ to steps 316′″ correspond to steps 304 to 316 but in respect of the 16^{th} packet. In step 330, the ACK message is generated in response to being triggered by the correct receipt of 16 packets, none of which have been acknowledged. The ACK timer maybe started on receipt of the first packet, i.e. packet 0 and restarted after the reception of each correctly received packet. Steps 320 to 326 are generally as described in relation to FIG. 9, except the ACK packet will include information relevant to the last received packet, that is packet 15, the counter in the receiver is updated to have the next to receive packet as packet 16 and the last acknowledged packet as being 15. The sender in step 324 will delete all of packets 0 to 15 from memory and will in step 326 update the counter so the next to transmit packet is packet 16 and the last acknowledged packet is 15.

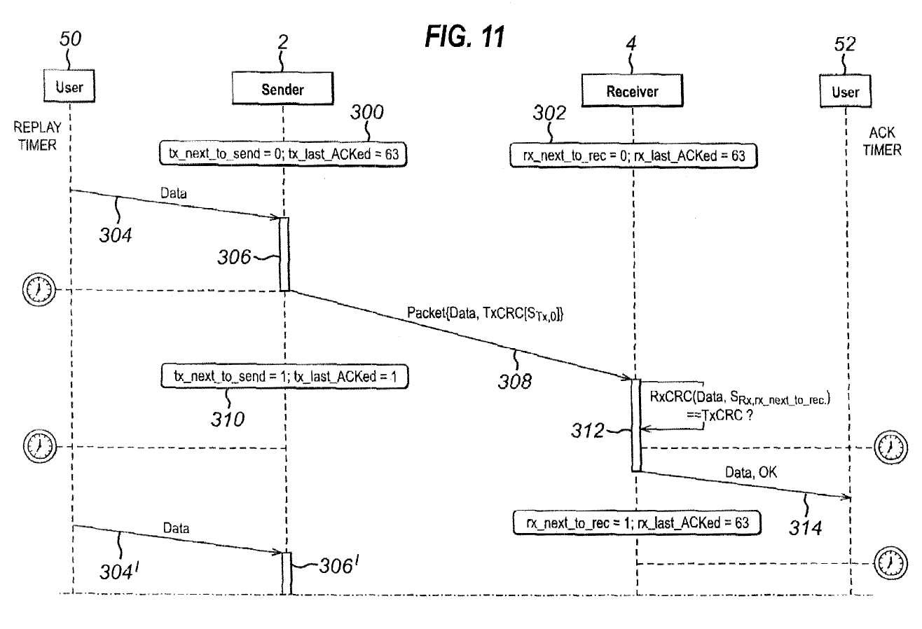

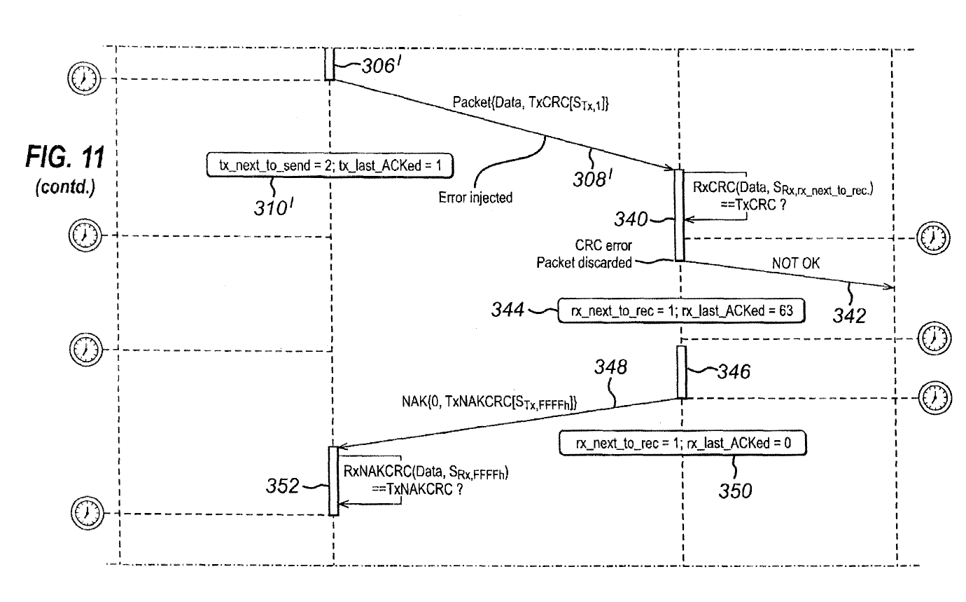

The erroneous data packet transmission with its negative acknowledgement and re-transmission of not acknowledged packet is now described with reference to FIG. 11.

Considered the following example, the sending node has determined that the next packet to send is 0 and the last acknowledged packet is 63. The sending node sends packet 0 to the receiving node which correctly receives that packet. However, no individual acknowledgement of that packet is sent at this time. This is indicated by steps 300 to 316 which correspond to those steps of FIG. 9.

The next to send packet is updated to packet 1 at the sending node in step 310. The packet number 1 is sent and the counter in the sending node is updated to 2. Steps 304′ to steps 308′ correspond to those steps of FIG. 10.

However, packet 1 is not correctly received by the receiver. Accordingly, a CRC error is noted in step 340 and the data is discarded in step 342. This means that the next to receive packet counter is not updated in the receiving node because the data was not received as shown in step 344. This triggers a non-acknowledgement NAK message to be prepared in step 346 and to be sent from the receiving node to the sender in step 348. This will include the seed value or the seed counter value of the packet which was correctly received. The seed value or seed counter value may alternatively be that of the packet which the receiver next expects to receive.

The sender processes the NAK signal in step 352, this causes the next to send counter to be updated to 1 again in step 354. The last acknowledged packet counter in both the sender and the receiver is updated to 1 and the next to receive/transmit packet is 1 as indicates in steps 350 and 354. In step 360 the sender prepares the next packet to send, that is the retransmission of packet 1. The next steps 306′ to 316′ correspond to those steps of FIG. 10. It should be appreciated that the ACK mechanism of FIG. 9 or 10 can be used in this example.

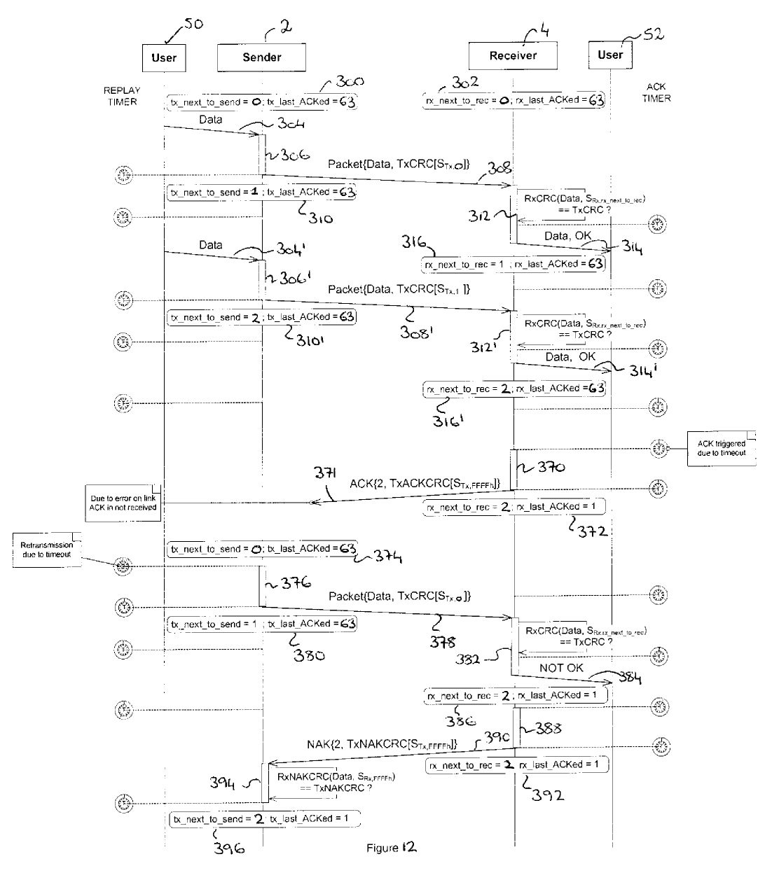

Consider this scenario where the packets sent from the sender to the receiver have been correctly received but due to an error an acknowledgement message is not received. This is described in relation to the message flow of FIG. 12. Steps 300 to 316′ are generally as described in relation to FIG. 10. In step 370, the receiver determines that an ACK message is to be sent, using for example the mechanism described in relation to FIG. 9 or in relation to FIG. 10. In step 371, the ACK packet is sent but is not received by the sender. In the receiver, the next to receive packet is updated to 2 and the last acknowledged packet to 1.

In the absence of receipt of an acknowledgement message within a predetermined time, the sending node looks at which packet was last acknowledged in step 376. As indicated by step 374, the counter indicates that the last acknowledged packet is 63 and the next to transmit packet is 0. This counter has been updated as a consequence of not receiving an ACK message in a predetermined time, as controlled by the replay timer in the sender. In step 378 the sender sends packet 0 again. This means that for example the sending node is resending packet 0 but the receiving node is expecting packet 2. In the sender the counter is updated to indicate that the next to send packet is 1.

In step 382, the receiving node will discard the re-transmitted packet 0 and discard the data in step 384. In step 386, the counter is unchanged. In step 388 the receiver prepares a NAK message and sends the non-acknowledgement NAK message to the receiver in step 390 which will indicate the next packet which it expects to receive, for example packet 2 or in the alternative, the last packet that was received by the receiver. In step 392, the counter in the receiver indicates that the next to receive packet is packet number 2 and the last acknowledged packet is packet 1.

This NAK packet is processed by the sender 2 in step 394 and will then cause the next to transmit counter to be updated to 2 and the last acknowledged packet to be updated to 1 in the sending node.

Because the acknowledgment and non-acknowledgement messages include the seed value or the seed counter value of the packet which has last been correctly received or is next expected, it is possible to bring the sending and receiving node back into synchronisation relatively quickly after a transmission error has occurred.

It should be appreciated that the particular values given for the size of the counters, window size and seed counter part to be used in the ACK/NAK message is by way of example only and other values can be used in alternative embodiments of the invention.

A further embodiment will now be described in a method for achieving a reliable and an unreliable link is proposed. In particular the packets that are transmitted from the sender to the receiver include additional information if it is a reliable (R) or an unreliable (U) packet. This may be indicated by setting an appropriate bit in an appropriated location to 1 or 0, representing the two types of packet. The bit may be in the header, the footer or the payload.

A reliable packet must be received and accordingly will be retransmitted if necessary. An unreliable packet does not need to be received by the receiver and in the event of a transmission error will not be retransmitted. The nodes of FIG. 8 may be used in this embodiment.

The sender will increment its seed counter (TX seed counter) only after a reliable packet is transmitted. If there is a transmission of an unreliable packet there is no modification of the TX seed counter after transmitting it. Unreliable packets are not stored in the TX buffer after transmission, because there is no need for retransmission of that type of packets. No acknowledgment is expected for unreliable packets.

The seed values are always different for successive reliable packets. The minimum number of different seed values used for successive reliable packets should be greater than the acknowledgement window size. The reliable packets have to be stored in the TX buffer until an acknowledgment is received form the receiver side.

The seed counter on receiver side (RX seed counter) is incremented after reception of every correctly received reliable packet. If an error is detected, the seed counter is not incremented and, hence, the seed value will not be updated (i.e. the same seed value will be used for the next received packet).

The receiver includes a part of the RX seed counter value (e.g. to allow an acknowledgement window size of 16, at least 5 bits are needed) in ACK/NAK packets to acknowledge correctly received packets.

The ACK and NAK communication is not modified (only reliable packets are acknowledged). It is same as described in relation to the second embodiment.

The sender removes the relevant number of packets (reliable packets) from the buffer corresponding to the part of the seed counter value that is received with the ACK/NAK packet from the receiver.

The counter value that is transmitted in the ACK or NAK could be either a part of RX seed counter bits or the complete RX seed counter bits.

Unreliable packets may have default CRC seed values used. The sending node would know to use the default CRC as it would have the information that the packet is unreliable. The receiving node would also know from the value of the relevant bit if the packet is reliable or unreliable. If the packet is unreliable then the receiving node would know to use the default CRC. Alternatively the seed value associated with the current count value could be used in the sending and receiving nodes, without any updating of the counters.

Embodiments of the invention may enable the transmission of reliable and unreliable packets over the same traffic class (virtual channel).

Embodiments of the invention may send a retransmission announcement packet before the actual retransmission of data packets. Behaviour in FIG. 12 may be different if that announcement would be used. In that case there would not be a NAK triggered after the timer expires.

Embodiments of the present invention can be implemented in the network system such as but not limited to the MIPI (mobile industry process interface) Alliance Standard for Unified Protocol (UniPro) in which communication is built on a layered protocol for interconnecting devices, components, circuits, modules etc. By way of example this may include but is not limited to cellular telephones, handheld computers, digital cameras and multimedia devices. Such a network allows these devices, components etc. to exchange data at high data rate, with low pin counts and at low energy per transferred bit. It is applicable to a wide range of component types such as application processors, co-processors, modems, etc. and to different types of data traffic such as control messages, bulk data transfer, packetised streaming etc. Thus, the term node is intended to encompass these interconnecting devices, components, circuits, modules etc.

Thus embodiments of the present invention use a sender node and a receiver node that use counters counting the numbers of packets transmitted or received correctly since the last synchronisation event, for example a reset or synchronisation packet. The value of this counter is used to derive the access point to the seed window. The seed values can be either generated by logical units with the help of a counter value or can be pre-computed and stored in memory. The seed values are non-repetitive within the seed window.

Embodiments of the present invention may have an advantage that there is no need for sequence numbers that are transmitted in every packet to detect either losses or duplication, or out of order delivery packets. Accordingly, embodiments of the present invention may not require a process that checks the sequence numbers per packet at the receiver. Thus, in embodiments of the present invention, the CRC has a dual purpose in that it provides a data integrity check and also an in order delivery check. This may mean that the size of the header or footer can be reduced as there is no requirement for the transmission of sequence numbers. This may reduce the protocol overhead that is added per packet and may give more flexibility to the allowed number of outstanding packets in a protocol with the sliding window scheme.

It should be appreciated that at least some of the embodiments of the present invention can be implemented at least partially in software. Accordingly, embodiments of the present invention also extend to a computer program comprising one or more executable components for implementing embodiments of the present invention.

1. A sending node comprising:
a processor configured to generate an error checking message, said error checking message being generated from data, said error checking message providing order information; and
a transmitter configured to transmit said error checking message and said data.

2. A sending node as claimed in claim 1, wherein said error checking message provides data integrity information.

3. A sending node as claimed in claim 1, wherein said processor is configured to generate said error checking message using a cyclic redundancy check technique.

4. A sending node as claimed in claim 1, wherein said processor is configured to generate a first error checking message from first data, and a second error checking message from second data, said first and second error checking messages providing the order of said first data and said second data.

5. A sending node as claimed in claim 1, wherein said processor is configured to generate first and second error checking messages using a cyclic redundancy check technique, different seed values being used to generate said first and second error checking messages.

6. A sending node as claimed in claim 5, wherein said processor comprises a counter, a value of said counter being associated a respective seed value.

7. A sending node as claimed in claim 6, wherein said processor comprises a look up table storing seed values, the value of the counter being used to access one of said seed values.

8. A sending node as claimed in claim 6, wherein said processor is arranged to generate said seed value from the value of said counter.

9. A sending node as claimed in claim 5, wherein said processor is arranged to use a plurality of seed values cyclically.

10. A sending node as claimed in claim 1, wherein said transmitter is configured to transmit said error checking message and said data in a packet.

11. A sending node as claimed in claim 1, comprising a reliability manager configured to receive information about the receipt of said data by a receiver.

12. A sending node as claimed in claim 11, wherein said transmitter is configured to resend said data and associated error checking message if information about the receipt of data by said receiver is not received within a predetermined time or if said information indicates that said data has either not been received or not received correctly by said receiver.

13. A sending node as claimed in claim 11, comprising a memory storing said data, wherein said data is deleted from said memory if information about correct reception of said data by said receiver is received.

14. A sending node as claimed in claim 5, said processor is configured to generate a first error checking message from first data, and a second error checking message from second data, said first and second error checking messages providing the order of said first data and said second data, said reliability manager being configured to receive information about the receipt of said first and/or second data by a receiver, said information comprising at least one of: at least part of the seed value or at least part of a counter value defining said seed value associated with a respective error checking message associated with said first and/or second data.

15. A sending node as claimed in claim 14, wherein said at least part of the seed value or at least part of said counter value is associated with the error checking message which is associated with the first and/or second data correctly received by the receiver or the first and/or second data expected by the receiver.

16. A sending node as claimed in claim 1, wherein said processor is arranged to determine if said data is to be sent as unreliable data or reliable data.

17. A sending node as claimed in claim 16, wherein said transmitter is arranged to transmit information indicating if said data is to be sent as unreliable data or reliable data.

18. A sending node as claimed in claim 16, wherein said processor is arranged to have a first mode of operation for reliable data and a second mode of operation for unreliable data.

19. A sending node as claimed in claim 18, wherein in the first mode of operation, but not the second mode of operation, said processor is arranged to resend data if said data is not correctly received by said receiver.

20. A sending node as claimed in claim 18, wherein the node is configured to use a series of seed values, wherein the seed value selected is updated in said first mode for the transmission of different data but not updated in said second mode for the transmission of different data.

21. A sending node as claimed in claim 20, comprising a counter, different values of which are associated with different seed values, wherein said first mode said counter is updated for the transmission of different data but not in the second mode for the transmission of different data.

22. A sending node comprising:
processor means for generating an error checking message, said error checking message being generated from data, said error checking message providing order information; and
transmitter means for transmitting said error checking message and said data.

23. A method comprising:
generating an error checking message from data, said error checking message providing order information; and
transmitting said error checking message and said data.

24. A computer readable medium having computer executable components comprising:
a computer executable component configured to generating an error checking message from data, said error checking message providing order information.

25. A computer readable medium as claimed in claim 24, where said computer executable component is configured to generate said error checking message using a cyclic redundancy check technique.

26. A computer readable medium as claimed in claim 24, wherein said computer executable component is configured to generate a first error checking message from first data, and a second error checking message from second data, said first and second error checking messages providing the order of said first data and said second data.

27. A computer readable medium as claimed in claim 24, wherein said computer executable component is configured to generate first and second error checking messages using a cyclic redundancy check technique, different seed values being used to generate said first and second error checking messages.

28. A receiving node comprising:
a processor configured to generate an error checking message, said error checking message being generated from received data, said error checking message providing order information and to determine if said received data has been correctly received in dependence on said error checking message.

29. A receiving node as claimed in claim 28, comprising a receiver configured to receive said data and an associated error message, wherein said processor is configured to determine if said received data has been correctly received by comparing said generated error checking message with said associated error message.

30. A receiving node as claimed in claim 28, comprising a reliability manager configured to send a message indicating if data has been received correctly.

31. A receiving node as claimed in claim 30, wherein said message comprises information associated with an error message.

32. A receiving node as claimed in claim 31, wherein said message comprises information associated with one of an error message of data which is expected to be received and an error message associated with correctly received data.

33. A receiving node as claimed in claim 30, wherein said reliability manager is configured to send an acknowledgment message if data or a plurality of data have been correctly received.

34. A receiving node as claimed in claim 30, wherein said reliability manager is configured to send a non acknowledgement message if data or a plurality of data has not been correctly received.

35. A receiving node comprising:
means for generating an error checking message, said error checking message being generated from received data, said error checking message providing order information; and
means for determining if said received data has been correctly received in dependence on said error checking message.

36. A receiving node as claimed in claim 35, where said means for generating an error checking message is configured to generate said error checking message using a cyclic redundancy check technique.

37. A receiving node as claimed in claim 35, where said means for generating an error checking message is configured to generate a first error checking message from first data, and a second error checking message from second data, said first and second error checking messages providing the order of said first data and said second data.

38. A receiving node as claimed in claim 35, where said means for generating an error checking message is configured to generate first and second error checking messages using a cyclic redundancy check technique, different seed values being used to generate said first and second error checking messages.

39. A method comprising:
generating an error checking message from received data, said error checking message providing order information; and
determining if said received data has been correctly received in dependence on said error checking message.

40. A method as claimed in claim 39, where said generating an error checking message comprises generating said error checking message using a cyclic redundancy check technique.

41. A method as claimed in claim 39, where said generating an error checking message comprises generating a first error checking message from first data, and a second error checking message from second data, said first and second error checking messages providing the order of said first data and said second data.

42. A method as claimed in claim 39, where said generating an error checking message comprises generating first and second error checking messages using a cyclic redundancy check technique, different seed values being used to generate said first and second error checking messages.

43. A computer readable medium having computer executable components comprising:
a first computer executable component configured to generate an error checking message from received data, said error checking message providing order information; and
a second computer executable component configured to determine if said received data has been correctly received in dependence on said error checking message.

44. A computer readable medium as claimed in claim 43, where said first computer executable component is configured to generate said error checking message using a cyclic redundancy check technique.

45. A computer readable medium as claimed in claim 43, wherein said second computer executable component is configured to compared said error checking message with an error checking message received with said data.
